(19) United States
(12) Patent Application Publication
(10) Pub. No.: US 2009/0294877 A1
(43) Pub. Date: Dec. 3, 2009

(54) SEMICONDUCTOR DEVICE AND MANUFACTURING METHOD THEREOF

(76) Inventor: Masafumi TSUTSUI, Nara (JP)

Correspondence Address: MCDERMOTT WILL & EMERY LLP, 600 13TH STREET, NW, WASHINGTON, DC, 20005-3096, US

(21) Appl. No.: 12/416,597

(22) Filed: Apr. 1, 2009

(30) Foreign Application Priority Data
Jun. 2, 2008 (JP) 2008-144763

(51) Int. Cl. H01L 29/78; H01L 21/28

(52) U.S. Cl. 257/411; 438/591; 438/680; 257/E21.177; 257/E29.255

(57) ABSTRACT

In a semiconductor device, a gate insulating film is formed on a semiconductor substrate, and a gate electrode is formed on the gate insulating film. Thick regions of the gate insulating film which are located under both ends of the gate electrode, respectively, have a larger thickness than that of a middle region of the gate insulating film which is located under a middle region of the gate electrode.

### CROSS-REFERENCE TO RELATED APPLICATIONS

This application claims priority under 35 U.S.C. §119(a) based on Japanese Patent Application No. 2008-144763 filed on Jun. 2, 2008, the entire contents of which are hereby incorporated by reference.

### BACKGROUND

The present invention generally relates to a semiconductor device and a manufacturing method thereof. More particularly, the present invention relates to a field effect transistor (FET) including a gate insulating film having a high dielectric constant insulating film (high-k insulating film) and a manufacturing method thereof.

With recent improvement in integration level of semiconductor integrated circuits, FETs have been increasingly reduced in dimensions to implement a shorter gate length (50 nm or less) and a thinner gate insulating film (about 2 nm or less equivalent oxide thickness). However, voltage scaling has not progressed so much, and a power supply voltage to FETs is currently in the range of 0.9 V to 1.2 V. As a result, an electric field strength as high as about 1×10⁶ V/cm is generated between a gate electrode and a drain region in a semiconductor substrate through a gate insulating film at the end of the gate electrode. When such a high electric field is applied to an extension region as a part of the drain region in the semiconductor substrate, a tunneling leakage current tends to be generated between the drain and the channel (GIDL: Gate Induced Drain Leakage), which is a main cause of a parasitic leakage current from the drain region of an FET. Since the GIDL accounts for the major portion of power consumption in a semiconductor integrated circuit fabricated with FETs, reducing the GIDL is industrially extremely useful.

Conventionally, the GIDL is reduced by increasing the thickness of a gate insulating film only under the ends of a gate electrode located close to a source region and a drain region of a field effect transistor. As known in the art, this structure can reduce the electric field concentration in an extension region as a part of a drain region formed in a semiconductor substrate. As a result, the GIDL can be reduced. Moreover, this structure can prevent the thickness of the gate insulating film from being increased in its middle region located under a middle region of the gate electrode. As a result, degradation in driving capability of the field effect transistor can be suppressed.

Hereinafter, a conventional manufacturing method of a semiconductor device will be described with reference to FIGS. 6A through 6C (e.g., see Japanese Patent Laid-Open Publication No. 2001-168330). More specifically, a method for increasing the thickness of a gate insulating film under the ends of a gate electrode will be described.

FIGS. 6A through 6C are cross-sectional views of a main part of a semiconductor device taken along the gate length direction, and sequentially illustrate the conventional manufacturing method of the semiconductor device.

First, in the step of FIG. 6A, a gate insulating film 102 is formed on the upper surface of a semiconductor substrate 101. For example, the gate insulating film 102 is made of a silicon oxide film formed by thermal oxidation. A polysilicon film is then formed on the upper surface of the gate insulating film 102 by a thermal CVD (Chemical Vapor Deposition) method. The polysilicon film is then patterned into a gate electrode pattern by lithography technology and dry etching technology. A gate electrode 103 made of the polysilicon film is thus formed.

In the step of FIG. 6B, the semiconductor substrate 101 and the gate electrode 103 are subjected to wet thermal oxidation in a water vapor (H₂O) atmosphere, for example, at 850° C. for 10 minutes. The side surfaces and the upper surface of the gate electrode 103 are thus oxidized. At this time, the semiconductor substrate 101 is also oxidized in the regions located on both sides of the gate electrode 103. A silicon oxide film 104 is thus formed. In this case, water vapor (H₂O) used in the wet thermal oxidation diffuses in the gate insulating film 102. Accordingly, the surface of the gate electrode 103 which is in contact with the gate insulating film 102 is also oxidized partially in a region close to the atmosphere. Since the volume of the silicon oxide film is about 1.4 times larger than that of the polysilicon film, the thickness of the gate insulating film 102 is increased in regions 102a located under the ends of the gate electrode 103. Moreover, like the gate electrode 103 made of the polysilicon film, the surface of the semiconductor substrate 101 which is in contact with the gate insulating film 102 is also oxidized partially in a region close to the atmosphere. The thickness of the regions 102a of the gate insulating film 102 can further be increased.

In the step of FIG. 6C, impurity ions are implanted to form extension regions 105. A silicon nitride film is then deposited over the semiconductor substrate 101, and the silicon nitride film and the silicon oxide film 104 are subjected to anisotropic dry etching, thereby forming sidewalls made of the silicon oxide film 104 and the silicon nitride film 106. Impurity ions are then implanted again to form source/drain regions 107.

### SUMMARY

The conventional method uses thermal oxidation to increase the thickness of the gate insulating film under the ends of the gate electrode. More specifically, silicon of the gate electrode and silicon of the semiconductor substrate are thermally oxidized in a water vapor atmosphere in the regions close to the gate insulating film under the ends of the gate electrode. This method therefore requires a high temperature thermal oxidization process.

In small FETs, a gate tunneling leakage current may be generated from a gate electrode through a gate insulating film due to the reduced thickness of the gate insulating film (2 nm or less equivalent oxide thickness). In order to suppress generation of the gate tunneling leakage current, it is necessary to use a high-k insulating film (an oxide film such as HfSiO, HfSiON, or HfO, or the oxide film containing a silicate or nitrogen and containing Al, Hf, Zr, or rare earth atoms such as La) as a gate insulating film, instead of a silicon oxide film or a silicon oxynitride film. High-k insulating films, however, have low heat resistance. For example, HfO is crystallized at about 500° C. Accordingly, if a high-k insulating film is used as a gate insulating film, the high-k insulating film is crystallized when a high-temperature thermal oxidation process (800° C. or higher) is performed to increase the thickness of the gate insulating film under the ends of the gate electrode. As a result, generation of the gate tunneling leakage current cannot be suppressed. It is therefore difficult to reduce the GIDL while suppressing generation of the gate tunneling leakage current by the conventional method which uses the high-temperature thermal oxidation process (800° C. or higher) to increase the thickness of the gate insulating film under the ends of the gate electrode.

The present invention can provide a semiconductor device and a manufacturing method thereof capable of reducing the GIDL even when an insulating film having a high-k insulating film is used as a gate insulating film.

More specifically, a semiconductor device according to the present invention includes: a semiconductor substrate; a gate insulating film formed on the semiconductor substrate and having a high-k insulating film; and a gate electrode formed on the gate insulating film. Thick regions of the gate insulating film which are located under both ends of the gate electrode, respectively, have a larger thickness than that of a middle region of the gate insulating film which is located under a middle region of the gate electrode.

In the above structure, an insulating film having a high-k insulating film is used as the gate insulating film. Generation of a gate tunneling leakage current can therefore be suppressed.

Moreover, the above structure can suppress electric field concentration near the ends of the gate electrode. As a result, the GIDL can be reduced.

In the semiconductor device of the present invention, the thick regions of the gate insulating film are preferably formed integrally with the middle region of the gate insulating film.

In the semiconductor device of the present invention, respective upper surfaces of the thick regions of the gate insulating film are preferably located higher than an upper surface of the middle region of the gate insulating film.

In the semiconductor device of the present invention, the thickness of the thick regions of the gate insulating film preferably increases in a direction from a middle of the gate insulating film toward ends thereof.

Preferably, the semiconductor device of the present invention further includes: offset spacers respectively formed on side surfaces of the gate electrode; and sidewall spacers respectively formed on the side surfaces of the gate electrode with the respective offset spacers interposed therebetween. Each of the offset spacers preferably has an inner offset spacer formed on a corresponding one of the side surfaces of the gate electrode, and an outer offset spacer formed on a corresponding one of the side surfaces of the gate electrode with a corresponding one of the inner offset spacers interposed therebetween. The inner offset spacers are preferably in contact with the thick regions of the gate insulating film, respectively. With this structure, further increase in thickness of the thick regions can be prevented even if oxidation or the like is performed after the thick regions are formed. Note that the inner offset spacers are made of, for example, a silicon oxide film, and the outer offset spacers are made of, for example, a silicon nitride film. The inner offset spacers preferably have an L-shaped cross section.

Preferably, the semiconductor device of the present invention further includes: an underlying insulating film which is formed between the semiconductor substrate and the high-k insulating film of the gate insulating film and which is made of silicon having a lower specific dielectric constant than that of the high-k insulating film and containing at least one of oxygen and nitrogen. This structure can prevent cations (metal ions) of the high-k insulating film and oxygen from forming a film between the semiconductor substrate and the gate insulating film.

In the semiconductor device of the present invention, the high-k insulating film is preferably made of an insulating metal oxide or an insulating metal silicate.

In the semiconductor device of the present invention, the high-k insulating film may be an insulating film containing a metal, and a density of the metal in the thick regions of the gate insulating film may be lower than that of the metal in the middle region of the gate insulating film.

In the semiconductor device of the present invention, the gate electrode preferably has a conductor film formed on the gate insulating film, and a silicon film formed on the conductor film. The conductor film is preferably made of a metal or a metal compound.

In the semiconductor device of the present invention, the high-k insulating film preferably has an amorphous structure. Generation of a gate tunneling leakage current can therefore be suppressed.

A method for manufacturing a semiconductor device according to the present invention includes the steps of: (a) forming a gate insulating film having a high-k insulating film on a semiconductor substrate; (b) forming a gate electrode on the gate insulating film; and (c) forming thick regions of the gate insulating film under both ends of the gate electrode, respectively, so that the thick regions have a larger thickness than that of a middle region of the gate insulating film which is located under a middle region of the gate electrode.

In a preferred embodiment described below, in the step (c), a CVD method using ozone is performed to form a silicon oxide film covering the gate electrode and to form the thick regions of the gate insulating film which have a larger thickness than that of the middle region of the gate insulating film. Preferably, the method further includes the steps of: (d) after the step (c), forming a silicon nitride film on the silicon oxide film, and (e) forming offset spacers made of the silicon oxide film and the silicon nitride film on the respective side surfaces of the gate electrode.

In another preferred embodiment described below, in the step (c), heat treatment or plasma treatment is performed in an ozone atmosphere to form the thick regions of the gate insulating film which have a larger thickness than that of the middle region of the gate insulating film.

### BRIEF DESCRIPTION OF THE DRAWINGS

FIG. 1 is a cross-sectional view showing a structure of a main part of a semiconductor device according to a first embodiment of the present invention;

FIGS. 2A, 2B, 2C, and 2D are cross-sectional views of a main part of a semiconductor device taken along the gate length direction, and sequentially illustrate a manufacturing method of the semiconductor device of the first embodiment;

FIGS. 3A, 3B, 3C, and 3D are cross-sectional views of a main part of a semiconductor device taken along the gate length direction, and sequentially illustrate the manufacturing method of the semiconductor device of the first embodiment;

FIG. 4 is a cross-sectional view showing a structure of a main part of a semiconductor device according to a modification of the present invention;

FIGS. 5A, 5B, 5C, and 5D are cross-sectional views of a main part of a semiconductor device taken along the gate length direction, and sequentially illustrate a manufacturing method of the semiconductor device of the modification; and

FIGS. 6A, 6B, and 6C are cross-sectional views of a main part of a semiconductor device taken along the gate length direction, and sequentially illustrate a conventional manufacturing method of a semiconductor device.

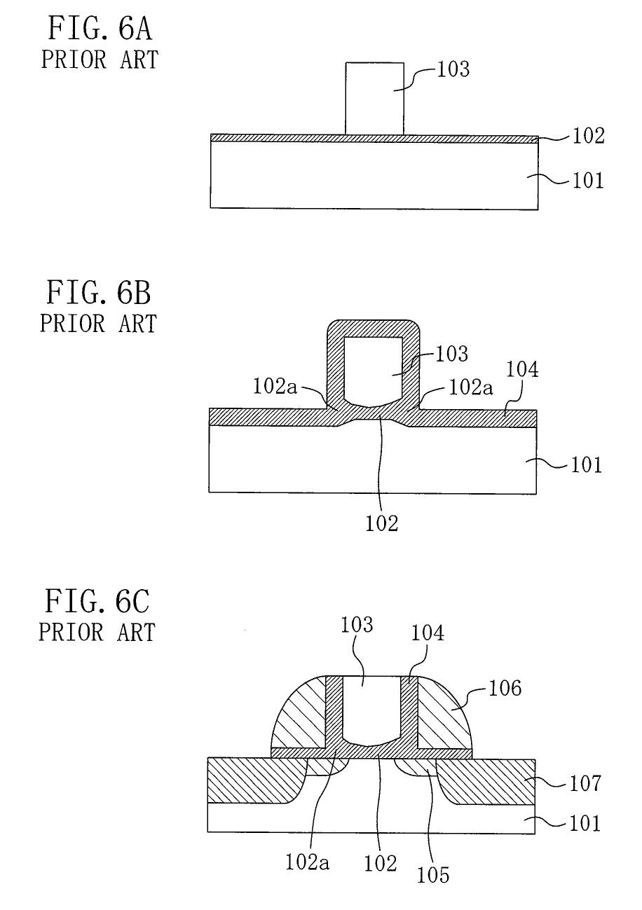

### DETAILED DESCRIPTION

Hereinafter, embodiments of the present invention will be described with reference to the accompanying drawings. Note that the present invention is not limited to the embodiments given blow. The same members are denoted with the same reference numerals and characters, and description thereof is sometimes omitted.

### First Embodiment

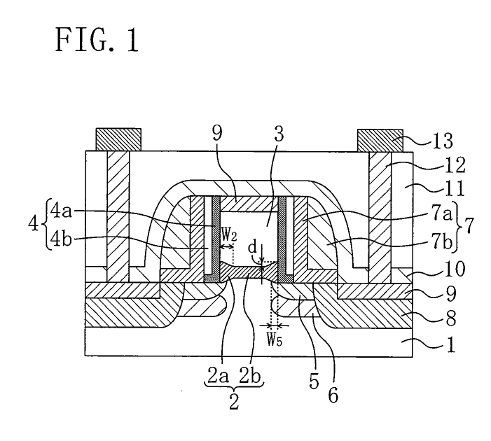

FIG. 1 is a cross-sectional view of a semiconductor device according to a first embodiment of the present invention.

As shown in FIG. 1, in the semiconductor device of the first embodiment, a semiconductor substrate 1 is made of silicon, and a gate insulating film 2 and a gate electrode 3 are sequentially formed on the upper surface of the semiconductor substrate 1. The gate insulating film 2 has a high-k insulating film which will be described later in detail. The gate insulating film 2 further has thick regions 2a and a middle region 2b (a region excluding the thick regions 2a). The thick regions 2a are located under both ends of the gate electrode 3, respectively, and the middle region 2b is located under a middle region of the gate electrode 3. The gate electrode 3 is made of a polysilicon film having a thickness of 50 nm to 100 nm.

Offset spacers 4 are respectively formed on the side surfaces of the gate insulating film 2 and the side surfaces of the gate electrode 3. Each offset spacer 4 has an inner offset spacer 4a and an outer offset spacer 4b. Each offset spacer 4 preferably has a thickness of about 5 nm to about 15 nm, but the respective thicknesses of the inner offset spacer 4a and the outer offset spacer 4b are not limited to any specific values. The inner offset spacers 4a are preferably made of a silicon oxide film, and are formed on the upper surface of the semiconductor substrate 1, the side surfaces of the gate insulating film 2, and the side surfaces of the gate electrode 3 so as to have an L-shaped cross section. The inner offset spacers 4a are respectively in contact with the thick regions 2a of the gate insulating film 2. The outer offset spacers 4b are preferably made of a silicon nitride film, and are formed on the side surfaces of the gate insulating film 2 and the side surfaces of the gate electrode 3 with the respective inner offset spacers 4a interposed therebetween.

Sidewall spacers 7 are formed on the side surfaces of the gate insulating film 2 and the side surfaces of the gate electrode 3 with the respective offset spacers 4 interposed therebetween. Each sidewall spacer 7 has an inner sidewall spacer 7a and an outer sidewall spacer 7b. The inner sidewall spacers 7a are preferably made of a silicon oxide film, and are formed on the side surfaces of the gate insulating film 2 and the side surfaces of the gate electrode 3 with the respective offset spacers 4 interposed therebetween. More specifically, each inner sidewall spacer 7a is formed on the upper surface of the semiconductor substrate 1 and the side surface of the corresponding outer offset spacer 4b so as to have an L-shaped cross section. The outer sidewall spacers 7b are preferably made of a silicon nitride film, and are formed on the side surfaces of the gate insulating film 2 and the side surfaces of the gate electrode 3 with the respective offset spacers 4 and the respective inner sidewall spacers 7a interposed therebetween.

Extension regions 5 are formed on both sides of the gate electrode 3 in the semiconductor substrate 1. The extension regions 5 are regions formed by implanting impurity ions to the semiconductor substrate 1 by using the gate electrode 3 and the offset spacers 4 as a mask. The extension regions 5 are formed so as to extend slightly under the gate electrode. The extension regions 5 preferably extend under the gate electrodes by a width W₅ of 5 nm or less depending on the gate length.

Pocket regions 6 are respectively formed under the extension regions 5 in the semiconductor substrate 1. Like the extension regions 5, the pocket regions 6 are regions formed by implanting impurity ions to the semiconductor substrate 1 by using the gate electrode 3 and the offset spacers 4 as a mask. The pocket regions 6 have a different conductivity type from that of the extension regions 5.

Source/drain regions 8 are respectively formed outside the extension regions 5 in the semiconductor substrate 1. The source/drain regions 8 are regions formed by implanting impurity ions to the semiconductor substrate 1 by using the gate electrode 3, the offset spacers 4, and the sidewall spacers 7 as a mask. Although not shown in the figure, a well region and a channel region which have the same conductivity type as that of the pocket regions 6 are formed in the semiconductor substrate 1.

In the case where the semiconductor device of the present embodiment is an N-type field effect transistor (N-type MISFET (Metal-Insulator Semiconductor Field-Effect Transistor), the extension regions 5 preferably contain 1×10¹⁵/cm² to 1×10¹⁶/cm² of N-type impurities (arsenic ions or the like), the pocket regions 6 preferably contain 1×10¹²/cm² to 1×10¹⁴/cm² of P-type impurities (boron ions or the like), and the source/drain regions 8 preferably contain 1×10¹⁶/cm² of N-type impurities (arsenic ions or the like).

In the semiconductor device of the present embodiment, a silicide layer 9 is formed on the upper surface of the gate electrode 3 and on the source/drain regions 8. The silicide layer 9 is preferably made of CoSi, NiSi, NiPtSi, or the like. A liner film 10 is formed on the upper surfaces of the offset spacers 4, on the sidewall spacers 7, and on the upper surface of the silicide layer 9 so as to cover the gate electrode 3 and the source/drain regions 8. The liner film 10 is preferably made of a silicon nitride film. An interlayer insulating film 11 is formed on the liner film 10. The interlayer insulating film 11 is preferably made of an insulating film such as a silicon oxide film. Contact plugs 12 are formed in the interlayer insulating film 11 so as to extend through the interlayer insulating film 11. The contact plugs 12 are connected to the silicide layer 9 formed on the upper surfaces of the source/drain regions 8, respectively, and are preferably made of W or Cu. Metal lines 13 are formed on the upper surface of the interlayer insulating film 11 in the regions connected to the contact plugs 12, respectively. The metal lines 13 are preferably made of a metal such as W, Cu, or Al.

The structure of the semiconductor device of the present embodiment is characterized in the following points:

The gate insulating film 2 has a high-k insulating film. The thickness of the gate insulating film can therefore be increased without causing degradation in capability of the semiconductor device, as compared to the case where the gate insulating film is made of a low dielectric constant insulating film (low-k insulating film) (an insulating film having a specific dielectric constant of less than 8, such as a silicon oxide film, a silicon nitride film, or a silicon oxynitride film). As a result, generation of a gate tunneling leakage current can be suppressed. Moreover, since this high-k insulating film has an amorphous structure, no grain boundary is present in this high-k insulating film. A leakage current flowing along grain boundaries can therefore be suppressed. As a result, generation of a gate tunneling leakage current can further be suppressed.

In the specification, the term “high-k insulating film” means an insulating film which has a higher specific dielectric constant than that of a silicon nitride film and which is made of an insulating metal oxide or an insulating metal silicate having a specific dielectric constant of 8 or more, and preferably 10 or more. For example, the high-k insulating film may either be a film made of an insulating metal oxide such as HfSiO, HfSiON, or HfO, or a film made of this insulating metal oxide which further contains a silicate or nitrogen and contains Al, Zr, or rare earth atoms such as La instead of Hf. Especially, provided that M indicates Hf, Al, Zr, or rare earth atoms such as La, the high-k insulating film is a film which is made of MSiO, MO, or MON and which, when deposited directly on silicon, reacts with silicon to form an SiO₂ film at the interface with silicon. M may herein indicate either only one kind of Hf, Al, Zr, and rare earth atoms such as La, or more than one kinds of Hf, Al, Zr, and rare earth atoms such as La.

The gate insulating film 2 has thick regions 2a. The thick regions 2a are respectively located under the ends of the gate electrode 3 in the gate insulating film 2, and the thickness of the thick regions 2a is larger than that of the region (middle region) 2b located under the middle region of the gate electrode 3. More specifically, the thickness of the thick regions 2a gradually increases in the direction from the middle of the gate insulating film 2 toward the ends thereof so that the upper surfaces of the thick regions 2a are located higher than the upper surface of the middle region 2b. The thick regions 2a are formed integrally with the middle region 2b. This structure can reduce electric field concentration at the ends of the gate electrode 3 and thus can reduce the GIDL, as compared to the case where the gate insulating film has a uniform thickness. Moreover, degradation in driving capability of the semiconductor device can be prevented as compared to the case where the electric field concentration at the ends of the gate electrode 3 is reduced by increasing the overall thickness of the gate insulating film. In other words, the GIDL can be reduced and degradation in driving capability of the semiconductor device can be prevented by forming the thick regions 2a of the insulating film 2 so that the thick regions 2a has a larger thickness than that of the middle region 2b.

The difference in thickness between the thick regions 2a and the middle region 2b (thickness difference “d”) is preferably about 1 nm to about 5 nm. The reason for this will now be described. It is considered that the thicker the thick regions 2a of the gate insulating film 2 are, the more the electric field concentration at the ends of the gate electrode 3 can be reduced and therefore the more the GIDL can be reduced. However, since the thick regions 2a are formed integrally with the middle region 2b, the thick regions 2a having a too large thickness may cause increase in thickness of the middle region 2b. Accordingly, increasing the thickness difference “d” may degrade the capability of the semiconductor device. The thickness difference “d” is therefore preferably about 1 nm to about 5 nm in order to reduce the GIDL while maintaining the capability of the semiconductor device.

A width W₂ of the thick regions 2 extending under the gate electrode 3 is preferably about 1 nm to about 10 nm depending on the gate length. The reason for this will now be described. It is considered that the larger the width W₂ is, the more the GIDL can be reduced. However, a too large width W₂ is equivalent to increase in overall thickness in the gate insulating film 2 and therefore causes degradation in driving capability of the semiconductor device. Accordingly, the width W₂ of the thick regions 2a extending under the gate electrode 3 is preferably about 1 nm to about 10 nm in order to reduce the GIDL while maintaining the capability of the semiconductor device. Moreover, if the width W₂ of the thick regions 2a under the gate electrode 3 is larger than the width W₅ of the extension regions 5 under the gate electrode 3, the electric field concentration at the ends of the gate electrode 3 can be reduced as compared to the case where the width W₂ is equal to or smaller than the width W₅. Therefore, the GIDL can be reduced when the width W₂ is larger than the width W₅.

The thick regions 2a are formed by performing a CVD method using ozone at a temperature less than the crystallization temperature of the high-k insulating film as described below, or by performing heat treatment or plasma treatment in an ozone atmosphere at a temperature less than the crystallization temperature of the high-k insulating film as described later in a modification. Although the mechanism of how the thick regions 2a are formed is still unclear, the inventor has considered the following three mechanisms: a first mechanism is that the thickness of the high-k insulating film itself is increased; a second mechanism is that at least one of the semiconductor substrate 1 and the gate electrode 3 is oxidized near the ends of the gate electrode 3; and a third mechanism is that the first and second mechanisms occur at the same time. In the case where the thick regions 2a are formed by the first mechanism, the high-k insulating film is dominant in the gate insulating film 2. However, the amount of a metal (e.g., Hf) of the high-k insulating film in the thick regions 2a does not increase from the amount before the thickness is increased. Therefore, the density of the metal of the high-k insulating film is lower in the thick regions 2a than in the middle region 2b. In the case where the thick regions 2a are formed by the second mechanism, an insulating metal oxide or an insulating metal silicate of the high-k insulating film is dominant in the middle region 2b, while not only the insulating metal oxide or the insulating metal silicate of the high-k insulating film but a silicon oxide are present in the thick regions 2a. Accordingly, the density of the metal of the high-k insulating film is lower in the thick regions 2a than in the middle region 2b. As described above, it is considered that the density of the metal of the high-k insulating film is lower in the thick regions 2a than in the middle region 2b in both the first mechanism and the second mechanism. It can therefore be considered that, in the third mechanism as well, the density of the metal of the high-k insulating film is lower in the thick regions 2a than in the middle region 2b. In any of the above three mechanisms, the thick regions 2a are formed under both ends of the gate electrode 3 in the gate insulating film 2. Moreover, the thick regions 2a of the gate insulating film 2 are formed at a temperature lower than the crystallization temperature of the high-k insulating film. The thick regions 2a can therefore be formed without involving crystallization of the high-k insulating film. In the present embodiment, generation of a gate tunneling leakage current can be suppressed and the GIDL can be reduced without causing degradation in driving capability of the semiconductor device.

As has been described above, since the gate insulating film 2 of the semiconductor device of the present invention has a high-k insulating film having an amorphous structure, generation of a gate tunneling leakage current can be suppressed. Moreover, since the gate insulating film 2 has the thick regions 2a under the ends of the gate electrode 3, the GIDL can be reduced. As a result, power consumption of the semiconductor device can be reduced.

Since the thick regions 2a are formed only under the ends of the gate electrode 3 in the gate insulating film 2, increase in thickness of the middle region 2b can be suppressed. Accordingly, power consumption of the semiconductor device can be reduced without causing degradation in driving capability of the semiconductor device.

In order to reduce the GIDL and suppress generation of a gate tunneling leakage current without causing degradation in driving capability of the semiconductor device, the semiconductor device is manufactured without involving crystallization of the high-k insulating film, the difference in thickness (thickness difference “d”) between the thick regions 2a and the middle region 2b is set to about 1 nm to about 5 nm, and the width W₂ of the thick regions 2a under the gate electrode 3 is set to about 1 nm to about 10 nm. Such a semiconductor device (especially the thick regions 2a) is manufactured by the following method:

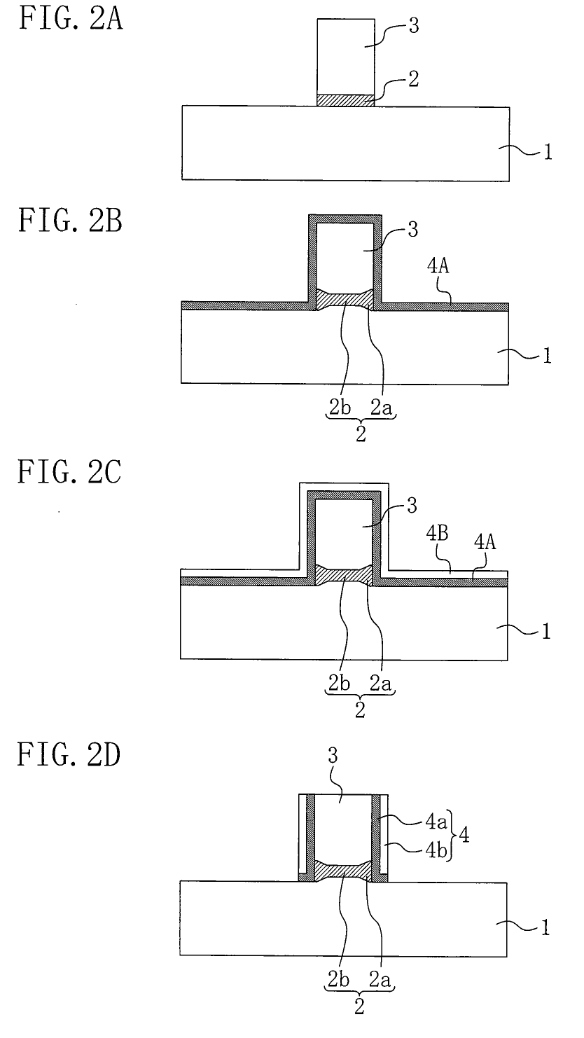

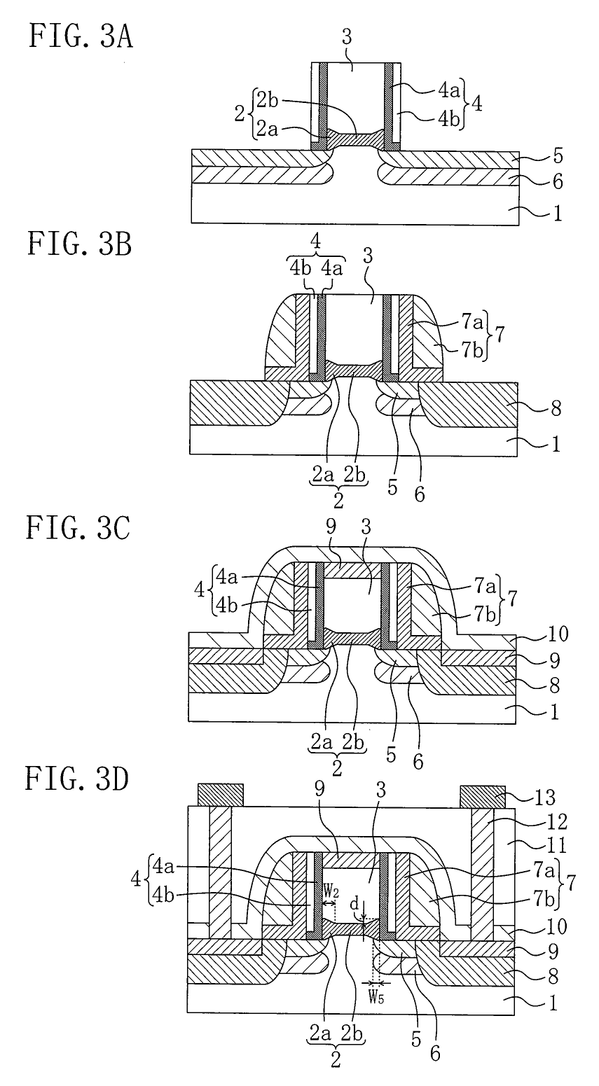

FIGS. 2A through 2D and FIGS. 3A through 3D are cross-sectional views showing a main part of a semiconductor device taken along the gate length direction, and sequentially illustrate a manufacturing method of the semiconductor device of the first embodiment. A manufacturing method of an N-type FET (N-type MISFET) will be described herein as an example.

In the step of FIG. 2A, a high-k insulating film having a thickness of 2 nm to 3 nm is formed on a semiconductor substrate 1 by a MOCVD (Metal-Organic Chemical Vapor Deposition) method (step (a)), and a polysilicon film having a thickness of 50 nm to 100 nm is then formed on the high-k insulating film by a CVD method (step (b)). The semiconductor substrate 1 is made of silicon. Note that, although not shown in the figure, a P-type well region and a P-type channel region are formed in the semiconductor substrate 1. The high-k insulating film and the polysilicon film are then patterned to form a gate insulating film 2 made of the high-k insulating film and a gate electrode 3 made of the polysilicon film on the semiconductor substrate 1. For example, the gate electrode 3 is formed by etching the polysilicon film by anisotropic dry etching with a CF₄ gas, and the gate insulating film 2 is formed by wet-etching the high-k insulating film. Note that, in the present embodiment, the high-k insulating film is an insulating film which has a higher specific dielectric constant than that of a silicon nitride film and which is made of an insulating metal oxide or an insulating metal silicate having a specific dielectric constant of 8 or more, and preferably 10 or more. For example, the high-k insulating film is an insulating film formed by using a high-k material such as HfO₂, HfSiO₂, HfSiON, or HFAlOX.

In the step of FIG. 2B, a silicon oxide film 4A having a thickness of 1 nm to 10 nm is formed over the semiconductor substrate 1 so as to cover the gate insulating film 2 and the gate electrode 3. The silicon oxide film 4A is formed by a reduced pressure CVD method using tetraethoxysilane (TEOS) and ozone (O₃) (the deposition temperature (e.g., 600° C.)<the crystallization temperature of the high-k insulating film). At this time, thick regions 2a of the gate insulating film 2 are also formed at the ends of the gate electrode 3 (step (c)). The thickness of the thick regions 2a is larger than that of a middle region 2b of the gate insulating film 2 by about 1 nm to about 5 nm. The thick regions 2a are thus formed integrally with the middle region 2b. The thickness of the thick regions 2a increases in the direction from the middle of the gate insulating film 2 toward the ends thereof, and the upper surfaces of the thick regions 2a are located higher than the upper surface of the middle region 2b.

The mechanism of how the thick regions 2a are formed in the gate insulating film 2 is still unclear. However, the inventor confirmed that the thick regions 2a are not formed by a normal CVD method using oxygen (O₂) but are formed by a CVD method using ozone (O₃). Based on this fact, the inventor has considered that the thick regions 2a are formed in the gate insulating film 2 by any of the following mechanisms: the thickness of the high-k insulating film itself is increased near the ends of the gate electrode 3 due to oxygen resulting from decomposition of ozone having a strong oxidizability or due to ozone (the first mechanism); at least one of the semiconductor substrate 1 and the gate electrode (polysilicon film) 3 is oxidized near the ends of the gate electrode 3 to form a silicon oxide film (the second mechanism); and the first mechanism and the second mechanism are combined (the third mechanism).

It is herein assumed that an HfO₂ film containing Hf (metal) is used as the high-k insulating film. In the case where the thick regions 2a are formed in the gate insulating film 2 by the first mechanism, the high-k insulating film is dominant in the gate insulating film 2. However, the amount of the metal (e.g., Hf) of the high-k insulating film in the thick regions 2a does not increase from the amount before the thickness is increased. The density of Hf (metal) is therefore lower in the thick regions 2a than in the middle region 2b. In the case where the thick regions 2a are formed in the gate insulating film 2 by the second mechanism, at least one of the semiconductor substrate 1 and the gate electrode 3 is oxidized near the ends of the gate electrode 3. Accordingly, not only HfO₂ but a silicon oxide are present in the thick regions 2a of the gate insulating film 2. The density of Hf (metal) is therefore lower in the thick regions 2a than in the middle region 2b of the gate insulating film 2. In both the first mechanism and the second mechanism, the density of Hf (metal) is lower in the thick regions 2a than in the middle region 2b of the gate insulating film 2. It can therefore be considered that, in the third mechanism as well, the density of Hf (metal) is lower in the thick regions 2a than in the middle region 2b of the gate insulating film 2.

It is desirable that the width W₂ of the thick regions 2a under the gate electrode 3 is larger than the width W₅ of extension regions 5 (which are formed in the step described below) under the gate electrode 3, and the width W₂ may be in the range of about 1 nm to about 10 nm. Since the thick regions 2a having a too large width W₂ cause degradation in driving capability of the semiconductor device, it is desirable that the width W₂ is larger than the width W₅ by at most 5 nm. The width W₂ may become as large as 20 nm to 50 nm when the silicon oxide film 4A is formed by a CVD method in an ozone atmosphere at a high deposition temperature or at a high ozone partial pressure. It is therefore necessary to adjust the exposure time to a high temperature to optimize the width W₂.

Similarly, when the silicon oxide film 4A is formed by a CVD method in an ozone atmosphere at a high deposition temperature or at a high ozone partial pressure, the difference in thickness (thickness difference “d”) between the thick regions 2a and the middle region 2b may become much larger than 5 nm, or not only the thick regions 2a but also the middle region 2b may be increased in thickness. It is therefore preferable to adjust the exposure time to a high temperature so that the thickness difference “d” does not become much larger than 5 nm and so that the thickness of the middle region 2b is not increased.

Formation of the silicon oxide film 4A by the reduced pressure CVD method is stopped when the thickness difference “d” becomes about 1 nm to about 5 nm and the width W₂ becomes about 1 nm to about 10 nm. In other words, the time required for formation of the silicon oxide film 4A by the reduced pressure CVD method is not determined by the thickness of the silicon oxide film 4A itself but by the thickness of the thick regions 2a or the width W₂ of the thick regions 2a under the gate electrode 3.

In the step of FIG. 2C, a silicon nitride film 4B having a thickness of 1 nm to 10 nm is then formed on the silicon oxide film 4A by an ALD (Atomic Layer Deposition) method (step (d)). At this time, the thickness of the thick regions 2a does not increase because neither ozone nor oxygen is supplied to the thick regions 2a. The silicon nitride film 4B is formed after the thick regions 2a are formed in the gate insulating film 2. The silicon nitride film 4B blocks oxygen supply even when oxidation or the like is performed in a later step. Accordingly, increase in thickness of the thick regions 2a in the gate insulating film 2 can be suppressed. The thickness of the silicon nitride film 4B is determined by the thickness of the silicon oxide film 4A and the thickness of offset spacers 4 which are to be formed in a later step. For example, if the offset spacers 4 need to have a width of 12 nm, and the silicon oxide film 4A is formed with a thickness of 5 nm in order to obtain a desired thickness of the thick regions 2a (the thickness difference “d” is about 1 nm to about 5 mm), the width of the offset spacers 4 is adjusted by forming the silicon nitride film 4B with a thickness of 7 nm. The thick regions 2a can thus be formed in the gate insulating film 2 while ensuring the thickness of the offset spacers 4 which function as a mask for the extension regions 5 and pocket regions 6.

In the step of FIG. 2D, the silicon nitride film 4B and the silicon oxide film 4A are sequentially etched by anisotropic etching to form the offset spacers 4 on the side surfaces of the gate electrode 3 (step (e)). Each offset spacer 4 is formed by an inner offset spacer 4a made of the silicon oxide film and an outer offset spacer 4b made of the silicon nitride film. Each inner offset spacer 4a is formed on a corresponding one of the side surfaces of the gate electrode 3, and has an L-shaped cross section. Each outer offset spacer 4b is formed on a corresponding one of the side surfaces of the gate electrode 3 with a corresponding one of the inner offset spacers 4a interposed therebetween. The inner offset spacers 4a are in contact with the thick regions 2a of the gate insulating film 2, respectively.

In the step of FIG. 3A, by using the gate electrode 3 and the offset spacers 4 as a mask, arsenic ions are implanted as N-type impurities into the semiconductor substrate 1 at a dose of 1×10¹⁵/cm² to 1×10¹⁶/cm² at an implantation energy of 2 keV to 5 keV to form N-type extension regions 5. Boron ions are then implanted as P-type impurities into the semiconductor substrate 1 at a dose of 1×10¹²/cm² to 1×10¹⁴/cm² at an implantation energy of 10 keV to 15 keV to form P-type pocket regions 6.

In the step of FIG. 3B, a silicon oxide film having a thickness of 10 nm and a silicon nitride film having a thickness of 50 nm are then sequentially formed over the whole surface of the semiconductor substrate 1. The silicon nitride film and the silicon oxide film thus formed are then sequentially etched by anisotropic etching to form sidewall spacers 7 on the side surfaces of the gate electrode 3 with the offset spacers 4 interposed therebetween, respectively. Each sidewall spacer 7 is formed by an inner sidewall spacer 7a made of the silicon oxide film and an outer sidewall spacer 7b made of the silicon nitride film. Each inner sidewall spacer 7a is formed on a corresponding one of the side surfaces of the gate electrode 3 with a corresponding one of the offset spacers 4 interposed therebetween, and has an L-shaped cross section. Each outer sidewall spacer 7b is formed on a corresponding one of the side surfaces of the gate electrode 3 with a corresponding one of the offset spacers 4 and a corresponding one of the inner sidewall spacers 7a interposed therebetween. By using the gate electrode 3, the offset spacers 4, and the sidewall spacers 7 as a mask, arsenic ions are implanted as N-type impurities into the semiconductor substrate 1 at a dose of 1×10¹⁶/cm² at an implantation energy of 30 keV to form N-type source/drain regions 8. The semiconductor substrate 1 is then heat-treated in a nitrogen atmosphere at 1,050° C. for 10 seconds to activate the implanted impurities.

In the step of FIG. 3C, an Ni film having a thickness of 10 nm is formed over the semiconductor substrate 1, and the semiconductor substrate 1 is then heat-treated in a nitrogen atmosphere at 500° C. for 10 seconds to form nickel silicide over the source/drain regions 8 and the gate electrode 3. After the remaining unreacted Ni film is removed, heat treatment for stabilizing silicide is performed to form a silicide layer 9 made of nickel silicide. A liner film 10 having a thickness of 30 nm is then formed over the whole surface of the semiconductor substrate 1. The liner film 10 is made of a silicon nitride film.

In the step of FIG. 3D, a silicon oxide film having a thickness of 400 nm is formed on the liner film 10. The silicon oxide film thus formed is planarized to form an interlayer insulating film 11. Contact holes are then formed so as to extend through the interlayer insulating film 11 and the liner film 10 to the silicide layer 9 on the source/drain regions 8. Tungsten is then introduced into the contact holes to form contact plugs 12 which are electrically connected to the respective source/drain regions 8 through the silicide layer 9. Metal lines 13 connecting to the contact plugs 12 are then formed on the interlayer insulating film 11. The semiconductor device of the present embodiment can thus be manufactured.

As has been described above, in the manufacturing method of the semiconductor device of the present embodiment, the thick regions 2a can be formed only under the ends of the gate electrode 3 in the gate insulating film 2. Accordingly, the GIDL can be reduced without degrading the driving capability of the semiconductor device.

In the manufacturing method of the semiconductor device of the present embodiment, the thick regions 2a of the gate insulating film 2 are formed at a temperature less than the crystallization temperature of the high-k insulating film. Accordingly, as opposed to the case where the thick regions of the gate insulating film are formed at a temperature equal to or higher than the crystallization temperature of the high-k insulating film, crystallization of the high-k insulating film can be prevented, whereby generation of a gate tunneling leakage current can be suppressed.

In the manufacturing method of the semiconductor device of the present embodiment, formation of the silicon oxide film 4A is stopped and the silicon nitride film 4B is formed on the silicon oxide film 4A when the thickness of the thick regions 2a of the gate insulating film 2 reach a desired value (the thickness difference “d”: about 1 nm to about 5 nm) or when the width W₂ of the thick regions 2a under the gate electrode 3 reaches a desired value (about 1 nm to about 10 nm). The thick regions 2a of the gate insulating film 2 can therefore be prevented from becoming thicker than the desired thickness (the thickness difference “d”: about 1 nm to about 5 nm) even if oxidation or the like is performed after formation of the silicon nitride film 4B. Since the thickness of the thick regions 2a of the gate insulating film 2 and the width W₂ of the thick regions 2a under the gate electrode 3 can thus be controlled, the GIDL can be reduced without degrading the driving capability of the semiconductor device.

Although formation of the silicon oxide film 4A is stopped when the thickness of the thick regions 2a of the gate insulating film 2 reach a desired value (the thickness difference “d”: about 1 nm to about 5 nm), a sufficient thickness of the offset spacers 4 can be assured because the silicon nitride film 4B is formed on the silicon oxide film 4A in the subsequent step and the offset spacers 4 are formed by the silicon oxide film 4A and the silicon nitride film 4B. Accordingly, the width W₅ of the extension regions 5 under the gate electrode 3 can be reduced while reducing the GIDL.

Note that the semiconductor device of the present embodiment may have the following structure.

A silicon oxide film or a silicon oxynitride film may be formed between the gate insulating film 2 and the gate electrode 3.

The gate insulating film may have a region (a high concentration region) with a relatively high concentration of rare earth atoms such as La or a relatively high concentration of Al in an upper part of the gate insulating film. In this case, the work function of the gate electrode can be reduced as compared to the case where the gate insulating film does not have such a high concentration region. As a result, a semiconductor device having a low threshold value can be implemented. The thickness of the high concentration region is 0.1 nm to 2.0 nm depending on the thickness of the gate insulating film.

A silicon oxynitride film may be used instead of the silicon oxide film of the embodiment.

The offset spacers may be a single-layer film. For example, the offset spacers may be formed only by a silicon oxide film, a silicon nitride film, or a silicon oxynitride film.

The sidewall spacers may be a single-layer film. For example, the sidewall spacers may be formed only by a silicon oxide film, a silicon nitride film, or a silicon oxynitride film.

The gate electrode may be a conductor film made of a metal such as Al, W, or Ti or a metal compound such as TiN or TaN, or may be a lamination of the conductor film and a polysilicon film as described later in a modification.

The inner offset spacers may cover only the side surfaces of the gate insulating film and the side surfaces of the gate electrode. The cross-sectional shape of the inner offset spacers is not limited to the L-shape.

The semiconductor device of the present embodiment may be manufactured by the following manufacturing method.

The gate insulating film 2 may be formed by an ALD method.

After the high-k insulating film is formed, a cap film containing rare earth atoms (such as La) or Al and having a thickness of about 0.1 nm to about 2 nm may be formed on the high-k insulating film. Note that, after the cap film is formed, the cap film may be integrated with the high-k insulating film and may serve as the high concentration region provided in the upper part of the gate insulating film in the manufactured semiconductor device.

The silicon nitride film 4B may not necessarily be formed if the thickness of the silicon oxide film 4A formed in the step of FIG. 2C is equal to a desired thickness (about 15 nm) of the offset spacers 4.

The silicon oxide film 4A may be formed by using an ALD method or a PVD (Physical Vapor Deposition) method.

The side surfaces of the gate insulating film 2 and the side surfaces of the gate electrode 3 may be nitrided before the step of forming the inner offset spacers 4a. This can prevent the thick regions 2a of the gate insulating film 2 from becoming thicker than the desired thickness (the thickness difference “d”: about 1 nm to about 5 nm).

The inner offset spacers 4a and the outer offset spacers 4b may be formed in separate steps. In other words, the silicon oxide film 4A may be etched to form the inner offset spacers 4a before formation of the silicon oxide film 4B. After formation of the inner offset spacers 4a, the silicon oxide film 4B may be formed and etched to form the outer offset spacers 4b. In this case, the inner offset spacers 4a need not necessarily have an L-shaped cross section, and may be formed so as to cover only the side surfaces of the gate insulating film 2 and the side surfaces of the gate electrode 3.

(Modification)

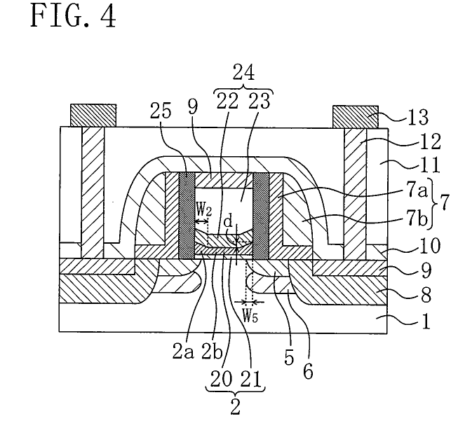

Hereinafter, a modification of the semiconductor device and the manufacturing method thereof according to the first embodiment of the present invention will be described. FIG. 4 is a cross-sectional view of the semiconductor device of the modification.

The semiconductor device of the modification is the same as the semiconductor device of the first embodiment in the following points: a gate insulating film 2 and a gate electrode 24 are sequentially formed on the upper surface of a semiconductor substrate 1 made of silicon; offset spacers 25 and sidewall spacers 7 are sequentially formed on the side surfaces of the gate insulating film 2 and the side surfaces of the gate electrode 24; and extension regions 5, pocket regions 6, and source/drain regions 8 are formed in the semiconductor substrate 1.

As in the first embodiment, the gate insulating film 2 has a high-k insulating film 20 having an amorphous structure, and has thick regions 2a having a larger thickness than that of a middle region 2b. With this structure, generation of a gate tunneling leakage current can be suppressed and the GIDL can be reduced while maintaining the driving capability of the semiconductor device.

An underlying insulating film 21 is formed between the semiconductor substrate 1 and the high-k insulating film 20 of the gate insulating film 2. The underlying insulating film 21 is preferably made of silicon having a lower specific dielectric constant than that of the high-k insulating film 20 and containing at least one of oxygen and nitrogen. For example, the underlying insulating film 21 is preferably made of a silicon oxide film or a silicon nitride film. The underlying insulating film 21 has a thickness of about 1 nm to about 2 nm. This structure can prevent a metal (e.g., Hf) of the high-k insulating film 20 from diffusing into the semiconductor substrate 1 to form a film between the semiconductor substrate 1 and the high-k insulating film 20 of the gate insulating film 2.

Unlike the gate electrode 3 of the first embodiment, the gate electrode 24 has a conductor film 22 and a silicon film 23. The conductor film 22 is formed on the upper surface of the gate insulating film 2, and is preferably made of a metal such as Al, W, or Ti or a metal compound such as TiN or TaN. The conductor film 22 has a thickness of 20 nm to 30 nm. The silicon film 23 is formed on the upper surface of the conductor film 22 and has a thickness of 30 nm to 70 nm. The silicon film 23 may be made of polysilicon or amorphous silicon.

Unlike the offset spacers 4 of the first embodiment, the offset spacers 25 are made of a single-layer film such as a silicon oxide film or a silicon oxynitride film. As in the first embodiment, however, the offset spacers 25 are respectively in contact with the thick regions 2a of the gate insulating film 2, and have a thickness of about 15 nm.

As has been described above, in the semiconductor device of the modification as well, the thick regions 2a of the first embodiment are formed in the gate insulating film 2. Accordingly, generation of a gate tunneling leakage current and generation of GIDL can be suppressed without degrading the capability of the semiconductor device.

Moreover, the underlying insulating film 21 is formed between the semiconductor substrate 1 and the high-k insulating film 20 of the gate insulating film 2. A metal of the high-k insulating film 20 can therefore be prevented from diffusing into the semiconductor substrate 1 to form a film between the semiconductor substrate 1 and the high-k insulating film 20 of the gate insulating film 2. This structure can therefore prevent degradation in capability of the semiconductor device.

Although the offset spacers 25 are made of a single-layer film, the offset spacers 25 have about the same thickness as that of the offset spacers 4 of the first embodiment. The offset spacers 25 therefore function as a mask for formation of the extension regions 5 and the pocket regions 6. Moreover, the offset spacers 25 are formed after the thick regions 2a are formed in the gate insulating film 2, as described below. This prevents further increase in thickness of the thick regions 2a of the gate insulating film 2.

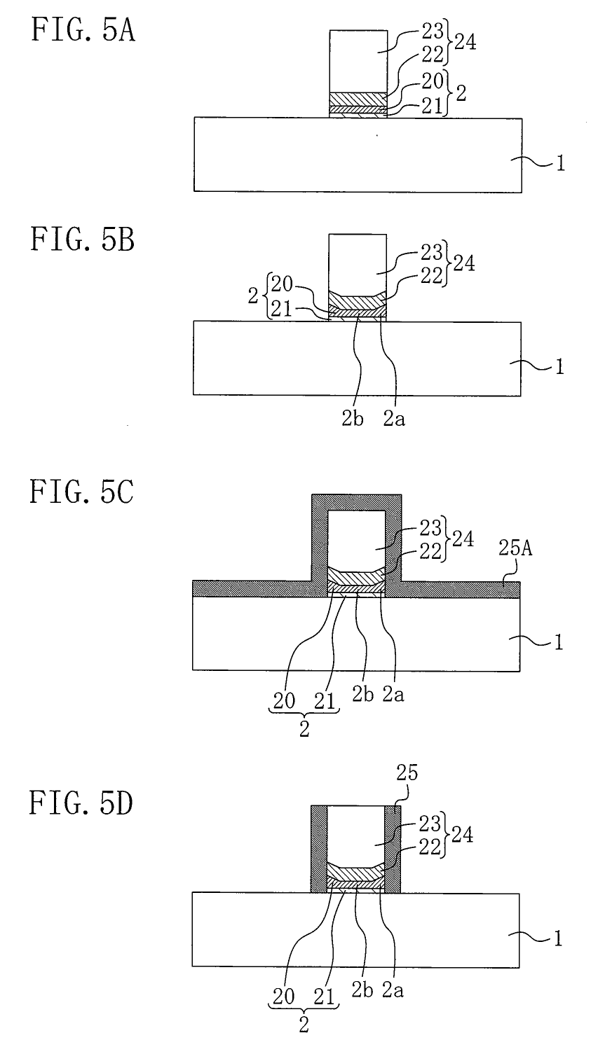

FIGS. 5A through 5D are cross-sectional views of a main part of the semiconductor device taken along the gate length direction, and sequentially illustrate a manufacturing method of the semiconductor device of the modification. A manufacturing method of an N-type FET (N-type MISFET) will be described herein as an example.

In the step of FIG. 5A, a silicon oxide film having a thickness of 1 nm to 2 nm is first formed on a semiconductor substrate 1 made of silicon. A high-k insulating film 20 having a thickness of 2 nm to 3 nm is then formed on the silicon oxide film by a MOCVD method. A TiN film having a thickness of 20 nm to 30 nm is then formed on the high-k insulating film 20, and a polysilicon film having a thickness of 30 nm to 70 nm is formed on the TiN film by a CVD method. The polysilicon film, the TiN film, the high-k insulating film 20, and the silicon oxide film are then patterned to form a gate insulating film 2, a conductor film 22, and a silicon film 23 over the semiconductor substrate 1. The gate insulating film 2 is formed by an underlying insulating film 21 made of the silicon oxide film, and the high-k insulating film 20 formed on the underlying insulating film 21. The conductor film 22 is made of the TiN film and is formed on the gate insulating film 2. The silicon film 23 is made of the polysilicon film and is formed on the conductor film 22. A gate electrode 24 formed by the conductor film 22 and the silicon film 23 is thus formed on the gate insulating film 2.

Note that, instead of the silicon oxide film, a silicon oxynitride film may be used as the underlying insulating film 21. Moreover, instead of the TiN film, a refractory conductor film such as a TaN film may be used as the conductor film 22. In the modification, an insulating film which has a higher specific dielectric constant than that of a silicon nitride film and which is made of an insulating metal oxide or an insulating metal silicate having a specific dielectric constant of 8 or more, and preferably 10 or more, can be used as the high-k insulating film 20, as described in the first embodiment. For example, an insulating film made of a high-k material such as HfO₂, HfSiO₂, HfSiON, or HfAlOₓ can be used as the high-k insulating film 20.

In the step of FIG. 5B, the ends of the gate insulating film 2 located under both ends of the gate electrode 24 are selectively oxidized by heat treatment in an ozone atmosphere or by ozone plasma to form thick regions 2a. At this time, almost no oxide film is formed on the exposed surface of the semiconductor substrate 1 and the exposed surface of the silicon film 23, while the thick regions 2a are formed under the ends of the gate electrode 3 in the gate insulating film 2. The thick regions 2a has a larger thickness than that of a middle region 2b of the gate insulating film 2 by about 1 nm to about 5 nm. The width W₂ of the thick region 2a from the end face of the gate insulating film 2 to the middle region 2b is about 1 nm to about 10 nm.

The mechanism of why the thickness of the gate insulating film 2 is increased only in the thick regions 2a is still unclear. However, the inventor confirmed that the exposed surface of the semiconductor substrate 1 or the silicon film 23 is oxidized by normal heat treatment in an oxygen (O₂) atmosphere or by oxygen plasma, while the thickness of the gate insulating film 2 is significantly increased only at its exposed ends by heat treatment in an ozone atmosphere or by ozone plasma.

It is now assumed that an HfO₂ film containing Hf (metal) is used as the high-k insulating film 20 of the gate insulating film 2 as in the first embodiment. In this modification, it can be considered that the thick regions 2a of the gate insulating film 2 are formed by a reaction between Hf contained in the high-k insulating film 20 of the gate insulating film 2 and ozone. Like the first embodiment, the density of Hf (metal) in the thick regions 2a of the gate insulating film 2 is therefore lower than that in the middle region 2b of the gate insulating film 2.

As in the first embodiment, it is desirable that the width W₂ of the thick regions 2a under the gate electrode 3 is larger than the width W₅ of the extension regions 5 extending under the gate electrode 3. Note that the thick regions 2a having a too large width W₂ cause degradation in characteristics of the semiconductor device. It is therefore desirable that the width W₂ is larger than the width W₅ by at most 5 nm.

In the step of FIG. SC, a silicon nitride film 25A having a thickness of 10 nm to 12 nm is formed on the semiconductor substrate 1 by an ALD method so as to cover the gate insulating film 2 and the gate electrode 24. At this time, the thickness of the thick regions 2a does not increase because neither ozone nor oxygen is supplied to the thick regions 2a.

In the step of FIG. SD, the silicon nitride film 25A is etched by anisotropic etching, whereby offset spacers 25 made of the silicon nitride film 25A are formed on the side surfaces of the gate electrode 24. The offset spacers 25 are in contact with the thick regions 2a of the gate insulating film 2, respectively. Accordingly, oxygen resulting from decomposition of ozone having a strong oxidizability, or ozone can be prevented from reacting with the high-k insulating film 20, whereby further increase in thickness of the thick regions 2a of the gate insulating film 2 can be prevented.

Thereafter, the same steps as those of FIGS. 3A through 3D are performed to sequentially form n-type extension regions 5, p-type pocket regions 6, sidewall spacers 7 each formed by an inner sidewall spacer 7a having an L-shaped cross section and an outer sidewall spacer 7b, n-type source/drain regions 8, a silicide layer 9, a liner film 10, an interlayer insulating film 11, contact plugs 12, and metal lines 13. The semiconductor device of FIG. 4 is thus obtained.

As has been described above, in the modification, generation of a gate tunneling leakage current can be suppressed and GIDL can be reduced without causing degradation in driving capability of the semiconductor device, as in the first embodiment. In addition, the semiconductor device can be manufactured while controlling the thickness of the thick regions 2a of the gate insulating film 2.

In the modification, a metal (e.g., Hf) of the high-k insulating film 20 can be prevented from forming a film between the semiconductor substrate 1 and the high-k insulating film 20 of the gate insulating film 2. The capability of the semiconductor device can further be improved.

What is claimed is:

1. A semiconductor device, comprising:
a semiconductor substrate;
a gate insulating film formed on the semiconductor substrate and having a high-k insulating film; and
a gate electrode formed on the gate insulating film, wherein
thick regions of the gate insulating film which are located under both ends of the gate electrode, respectively, have a larger thickness than that of a middle region of the gate insulating film which is located under a middle region of the gate electrode.

2. The semiconductor device of claim 1, wherein the thick regions of the gate insulating film are formed integrally with the middle region of the gate insulating film.

3. The semiconductor device of claim 1, wherein respective upper surfaces of the thick regions of the gate insulating film are located higher than an upper surface of the middle region of the gate insulating film.

4. The semiconductor device of claim 1, wherein the thickness of the thick regions of the gate insulating film increases in a direction from a middle of the gate insulating film toward ends thereof.

5. The semiconductor device of claim 1, further comprising:
offset spacers respectively formed on side surfaces of the gate electrode; and
sidewall spacers respectively formed on the side surfaces of the gate electrode with the respective offset spacers interposed therebetween, wherein
each of the offset spacers has an inner offset spacer formed on a corresponding one of the side surfaces of the gate electrode, and an outer offset spacer formed on a corresponding one of the side surfaces of the gate electrode with a corresponding one of the inner offset spacers interposed therebetween, and
the inner offset spacers are in contact with the thick regions of the gate insulating film, respectively.

6. The semiconductor device of claim 5, wherein
the inner offset spacers are made of a silicon oxide film, and
the outer offset spacers are made of a silicon nitride film.

7. The semiconductor device of claim 5, wherein the inner offset spacers have an L-shaped cross section.

8. The semiconductor device of claim 1, further comprising:
an underlying insulating film which is formed between the semiconductor substrate and the high-k insulating film of the gate insulating film and which is made of silicon having a lower specific dielectric constant than that of the high-k insulating film and containing at least one of oxygen and nitrogen.

9. The semiconductor device of claim 1, wherein the high-k insulating film is made of an insulating metal oxide or an insulating metal silicate.

10. The semiconductor device of claim 1, wherein
the high-k insulating film is an insulating film containing a metal, and
a density of the metal in the thick regions of the gate insulating film is lower than that of the metal in the middle region of the gate insulating film.

11. The semiconductor device of claim 1, wherein
the gate electrode has a conductor film formed on the gate insulating film, and a silicon film formed on the conductor film, and
the conductor film is made of a metal or a metal compound.

12. The semiconductor device of claim 1, wherein the high-k insulating film has an amorphous structure.

13. A method for manufacturing a semiconductor device, comprising the steps of:
(a) forming a gate insulating film having a high-k insulating film on a semiconductor substrate;
(b) forming a gate electrode on the gate insulating film; and
(c) forming thick regions of the gate insulating film under both ends of the gate electrode, respectively, so that the thick regions have a larger thickness than that of a middle region of the gate insulating film which is located under a middle region of the gate electrode.

14. The method of claim 13, wherein
in the step (c), a CVD method using ozone is performed to form a silicon oxide film covering the gate electrode and to form the thick regions of the gate insulating film which have a larger thickness than that of the middle region of the gate insulating film.

15. The method of claim 14, further comprising the steps of:
(d) after the step (c), forming a silicon nitride film on the silicon oxide film, and
(e) forming offset spacers made of the silicon oxide film and the silicon nitride film on the respective side surfaces of the gate electrode.

16. The method of claim 13, wherein
in the step (c), heat treatment or plasma treatment is performed in an ozone atmosphere to form the thick regions of the gate insulating film which have a larger thickness than that of the middle region of the gate insulating film.
